(19) United States
(12) Patent Application Publication
(10) Pub. No.: US 2021/0396784 A1
(43) Pub. Date: Dec. 23, 2021

(54) Device, and Method of Manufacture, for use in Mechanically Cleaning Nanoscale Debris from a Sample Surface

(71) Applicant: Bruker Nano, Inc., Santa Barbara, CA (US)

(72) Inventors: Weijie Wang, Thousand Oaks, CA (US); Shuiqing Hu, Santa Barbara, CA (US); Jason Osborne, Lompoc, CA (US); Chanmin Su, Ventura, CA (US)

(21) Appl. No.: 17/352,001

(22) Filed: Jun. 18, 2021

Related U.S. Application Data
(60) Provisional application No. 63/041,048, filed on Jun. 18, 2020.

(51) Int. Cl. G01Q 80/00

(52) U.S. Cl. CPC G01Q 80/00

(57) ABSTRACT

A mechanical method of removing nanoscale debris from a sample surface using an atomic force microscope (AFM) probe. The probe is shaped to include an edge that provides shovel-type action on the debris as the probe is moved laterally to the sample surface. Advantageously, the probe is able to lift the debris without damaging the debris for more efficient cleaning of the surface. The edge is preferably made by focused ion beam (FIB) milling the diamond apex of the tip.

### CROSS-REFERENCE TO RELATED APPLICATIONS

This application claims priority under 35 USC § 1.119(e) to United States Provisional Patent Application No. 63/041,048, filed Jun. 18, 2020. The subject matter of this application is hereby incorporated by reference in its entirety.

### BACKGROUND OF THE INVENTION

### Field of the Invention

The preferred embodiments are directed to a probe device for a metrology instrument and a corresponding method of manufacture, and more particularly, a probe device designed for mechanical cleaning of nanoscale debris on a surface, such as a lithography mask used in semiconductor fabrication. They additionally are directed to a method of using such a probe device and to an instrument having such a probe device.

### Description of Related Art

Semiconductor fabrication typically employs processes that require complicated equipment and components that are expensive. In one such example, the masks used in the lithography processes are complex expensive components that can cost tens of thousands and even hundreds of thousands of dollars to produce. During use, these masks are often left with nanometer scale debris on their surfaces such that they are not suitable for reuse unless they are cleaned.

In a known cleaning approach, an electron beam (EB) or laser beam is employed. EB or laser technology can be useful for this purpose, but has its limitations. For instance, the kinetic energy generated by the electron beam can burn the mask, in which case the mask is irrecoverably ruined. Moreover, EB techniques require the use of a precursor selected based on knowledge of the chemical composition and possibly other characteristics of its target. However, the characteristics of the debris are unknown, rendering the technique ineffective.

An appropriately tuned laser beam can be used to blast debris particles, but flash melting of the surface could lead to a defective part.

In the end, these techniques are known to clean about 20% of the debris that remains after use. This is unacceptable for components used in semiconductor fabrication—the masks ideally need to be essentially 100% free of debris to be reused.

As a result, a mechanical cleaning technique that at least essentially scrapes the nanoscale surface particles clean would be preferred. One option is to use a probe of a scanning probe microscope (SPM), such as the atomic force microscope (AFM).

As background information, AFMs are devices which use a sharp tip (radius less than 10 nm) for high resolution, and low forces to characterize the surface of a sample down to atomic dimensions. Generally, the tip of the SPM probe is introduced to the sample surface to detect changes in the characteristics of the sample. By providing relative scanning movement between the tip and the sample, surface characteristic data can be acquired over a particular region of the sample and a corresponding map of the sample can be generated.

An overview of AFM and its operation follows. A typical AFM system 10 is shown schematically in FIG. 1 employing a probe device 12 including a probe 14 having a cantilever 15. A scanner 24 generates relative motion between the probe 14 and sample 22 while the probe-sample interaction is measured. In this way images or other measurements of the sample can be obtained. Scanner 24 is typically comprised of one or more actuators that usually generate motion in three orthogonal directions (XYZ). Often, scanner 24 is a single integrated unit that includes one or more actuators to move either the sample or the probe in all three axes, for example, a piezoelectric tube actuator. Alternatively, the scanner may be an assembly of multiple separate actuators. Some AFMs separate the scanner into multiple components, for example an XY scanner that moves the sample and a separate Z-actuator that moves the probe. The instrument is thus capable of creating relative motion between the probe and the sample while measuring the topography or some other surface property of the sample as described, e.g., in Hansma et al. U.S. Pat. No. RE 34,489; Elings et al. U.S. Pat. No. 5,266,801; and Elings et al. U.S. Pat. No. 5,412,980.

In a common configuration, probe 14 is often coupled to an oscillating actuator or drive 16 that is used to drive probe 14 at or near a resonant frequency of cantilever 15. Alternative arrangements measure the deflection, torsion, or other motion of cantilever 15. Probe 14 is often a microfabricated cantilever with an integrated tip 17.

Commonly, an electronic signal is applied from an AC signal source 18 under control of an SPM controller 20 to cause actuator 16 (or alternatively scanner 24) to drive the probe 14 to oscillate. The probe-sample interaction is typically controlled via feedback by controller 20. Notably, the actuator 16 may be coupled to the scanner 24 and probe 14 but may be formed integrally with the cantilever 15 of probe 14 as part of a self-actuated cantilever/probe.

Often a selected probe 14 is oscillated and brought into contact with sample 22 as sample characteristics are monitored by detecting changes in one or more characteristics of the oscillation of probe 14, as described above. In this regard, a deflection detection apparatus 25 is typically employed to direct a beam towards the backside of probe 14, the beam then being reflected towards a detector 26. As the beam translates across detector 26, appropriate signals are processed at block 28 to, for example, determine RMS deflection and transmit the same to controller 20, which processes the signals to determine changes in the oscillation of probe 14. In general, controller 20 generates control signals to maintain a relative constant interaction between the tip and sample (or deflection of the lever 15), typically to maintain a setpoint characteristic of the oscillation of probe 14. More particularly, controller 20 may include a PI Gain Control block 32 and a High Voltage Amplifier 34 that condition an error signal obtained by comparing, with circuit 30, a signal corresponding to probe deflection caused by tip-sample interaction with a setpoint. For example, controller 20 is often used to maintain the oscillation amplitude at a setpoint value, AS, to insure a generally constant force between the tip and sample. Alternatively, a setpoint phase or frequency may be used.

A workstation 40 is also provided, in the controller 20 and/or in a separate controller or system of connected or stand-alone controllers, that receives the collected data from the controller and manipulates the data obtained during scanning to perform point selection, curve fitting, and distance determining operations.

AFM probes offer a decent option for nanosurface cleaning, but has its drawbacks. Turning to FIG. 2, due to the pyramidal shape of a regular probe tip 52 of a probe 50, when the tip pushes on surface defects/debris 56 laterally (e.g., on a wafer 54), the force applied on defect 56 has a significant component that pushes the defect downwardly. This can easily smash defect 56 into small pieces and/or increase adhesive forces holding the debris against the surface. As a result, as AFM tip 52 pushes the defect to clean the surface, a residue (not shown) may remain. This residue is difficult to clean. Surface cleaning using an AFM tip is further hindered by the fact that the only lifting forces that are available to lift the debris away from the surface are relatively low adhesive forces between the tip and the debris. AFM tips thus historically could not reliably achieve 100% cleanliness.

In view of the above, an improved method of mechanically removing nanoscale debris from a sensitive surface was therefore desired. A device/method capable of removing debris whole while preserving the surface integrity would be especially useful.

Note that “SPM” and the acronyms for the specific types of SPM's, may be used herein to refer to either the microscope apparatus, or the associated technique, e.g., “atomic force microscopy.”

### SUMMARY OF THE INVENTION

The preferred embodiments overcome the drawbacks of prior solutions by providing a method of removing debris that is able to essentially scoop up debris whole to transport the debris away from the surface to completely and reliably clean surfaces with little or no residue. The method preferably employs a unique probe to lift particles from hard but sensitive surfaces, such as on a photolithographic mask used in semiconductor fabrication.

A corresponding method of manufacture of the probe is also provided.

Diamond AFM probes have been used in nano indentation and nano modification of hard material surfaces for a long time. Modification of the diamond tip apex to shapes uniquely adapted to perform the lifting operation are particularly suitable for mask repair (cleaning) for the most advanced semiconductor industry wafer fab. In the preferred embodiments, Focus Ion Beam (FIB) technology is employed to Ga+ ion mill a notch in a surface of the pyramid diamond apex to form a blade shaped surface for sample surface cleaning. The diamond tip functions like a shovel to remove the unwanted hard materials (residual) from the sample surface, and thus repair the mask. The tip may also remain sharp enough to image the sample surface to identify defects prior to initiating the cleaning operation.

According to a first aspect of the preferred embodiment, a mechanical device for removing nanoscale debris from a sample surface includes a surface (engaging portion) configured to contact a bottom portion of the debris and lift the debris when moved laterally to the sample surface.

According to another aspect of the preferred embodiment, the mechanical device is an AFM probe having a tip, and the surface defines part of the tip. The tip is preferably a diamond tip, and the surface defines a notch formed between proximal and distal ends of the tip. The tip is a diamond tip, and the surface defines a notch formed between proximal and distal ends of the tip.

In a further aspect of this embodiment, the notch is formed by focus ion beam (FIB) milling, and the sample surface is a surface of a lithography mask used in semiconductor fabrication.

According to another aspect of the preferred embodiments, a cleaning method includes moving the tip in a vector laterally, and then moving vertically to capture the debris, resulting in scooping, in a shovel-like motion, of the debris from the sample surface.

In another aspect of the preferred embodiments, a method of manufacturing a device to clean nanoscale debris from a sample surface includes providing a probe having a diamond tip. The fabrication method includes modifying the tip such that when the probe is moved laterally to the sample surface and interacts with the nanoscale debris, the modified tip contacts a bottom portion of the debris so as to provide an upward (or lifting) force to the debris.

Also is provided is a SPM instrument having a tip having at least some of the characteristics described above and a method of operating such an SPM.

These and other objects, features, and advantages of the invention will become apparent to those skilled in the art from the following detailed description and the accompanying drawings. It should be understood, however, that the detailed description and specific examples, while indicating preferred embodiments of the present invention, are given by way of illustration and not of limitation. Many changes and modifications may be made within the scope of the present invention without departing from the spirit thereof, and the invention includes all such modifications.

### BRIEF DESCRIPTION OF THE DRAWINGS

A preferred exemplary embodiment of the invention is illustrated in the accompanying drawings in which like reference numerals represent like parts throughout, and in which:

FIG. 1 is a schematic illustration of a Prior Art atomic force microscope;

FIG. 2 is a schematic side elevational view of a standard pyramidal-shaped AFM probe tip being used in a Prior Art method to clean a sample surface of debris;

FIG. 3 is a schematic side elevational view of a Prior Art AFM probe having a pyramidal-shaped tip made of diamond;

FIG. 4 is a schematic side elevational view of a probe, starting as the prior art probe of FIG. 3, then focused ion beam (FIB) milled according to a preferred embodiment;

FIG. 5 is a schematic side elevational view of a probe similar to FIG. 2, but using the probe of FIG. 4 to illustrate the force exerted on debris during a lifting operation of the preferred embodiments;

FIG. 6 is a flow chart of a method for cleaning a surface of nanoscale debris using the probe shown in FIG. 4, according to a preferred embodiment; and

FIG. 7A-7E are a series of schematic side elevational views illustrating the removal of debris from a sample surface, according to a method of the preferred embodiments.

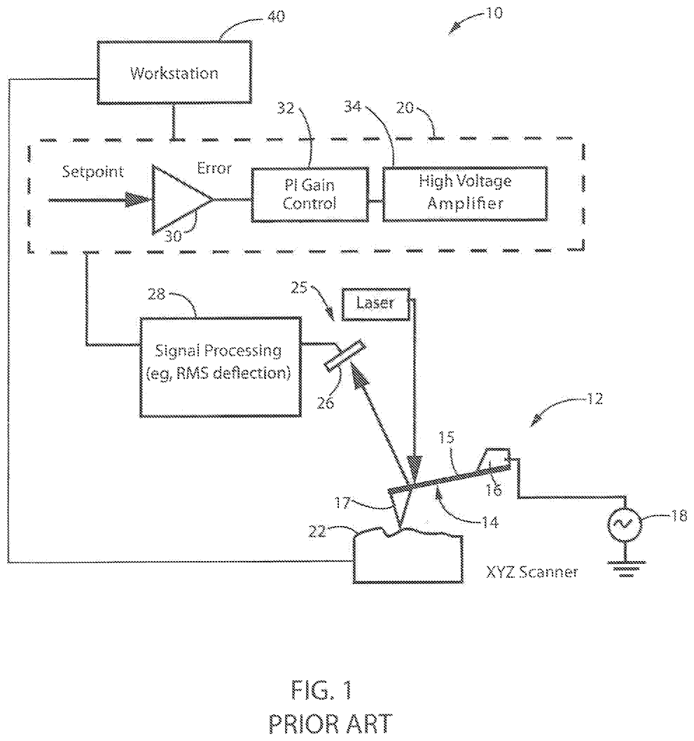

### DETAILED DESCRIPTION OF THE PREFERRED EMBODIMENTS

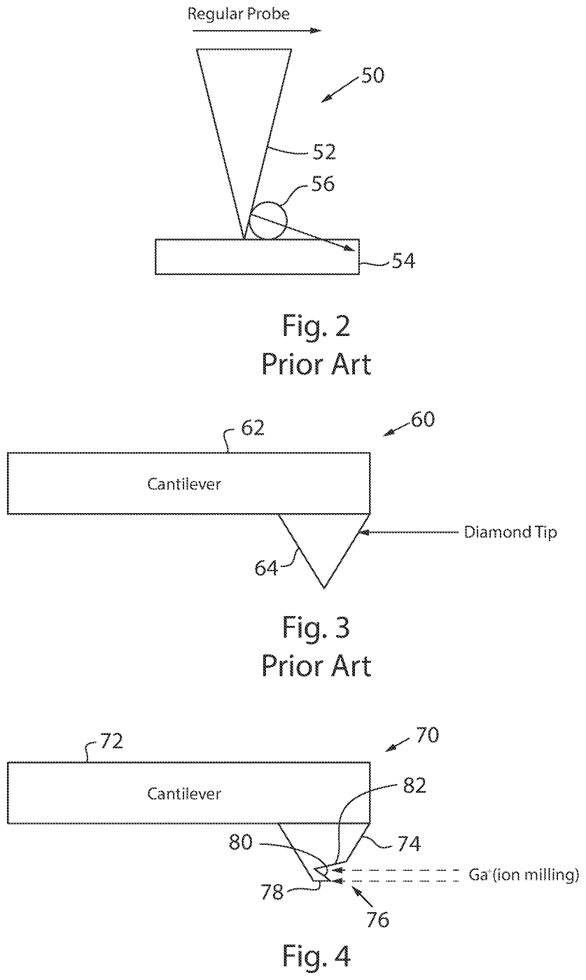

Referring initially to FIG. 3, a probe 60 is shown having a cantilever 62 and a pyramidal-shaped tip 64 typically used in an AFM, similar to that shown in FIG. 2. Tip 64 may be made of diamond. Starting with this probe, a probe 70 of a preferred embodiments includes a cantilever 72 supporting a tip 74 shaped to have a surface defining a notch 76 and to have a blunt distal end 78, as shown in FIG. 4. The surface is the outer surface of tip 74 in FIG. 4, but could be an inner surface or even a side surface. Blunt distal end 78 is not as sharp as a typical AFM tip used to image sub-nanometer features of samples, but it is sufficient to image the surface and provide a map of the debris prior to cleaning, as described further below in connection with the corresponding method.

In the preferred embodiments, focused ion beam (FIB) milling is used to form the surface so it is configured to lift debris as relative lateral motion is provided by the AFM scanner. As shown in FIG. 4, notch 76 of probe 70 is bordered at its bottom edge by an upper surface 80 of a wedge-shaped “blade.” When viewed in profile, this blade has a relatively planar lower surface 78 forming the blunt bottom of the tip and an upper surface 80 that slopes upwardly moving more inward to the body of the tip or to the rear in FIG. 4. In this embodiment, the notch is bordered at its upper edge by a tip surface 82 that slopes downwardly moving more inward to the body of the tip or to the rear in FIG. 4 The notch thus generally takes on the shape of a sideways “v”. The resultant modified tip is able to “shovel” or scoop up and carry away debris. As the AFM provides relative motion during the cleaning process, the debris may adhere and/or wedge in notch 76.

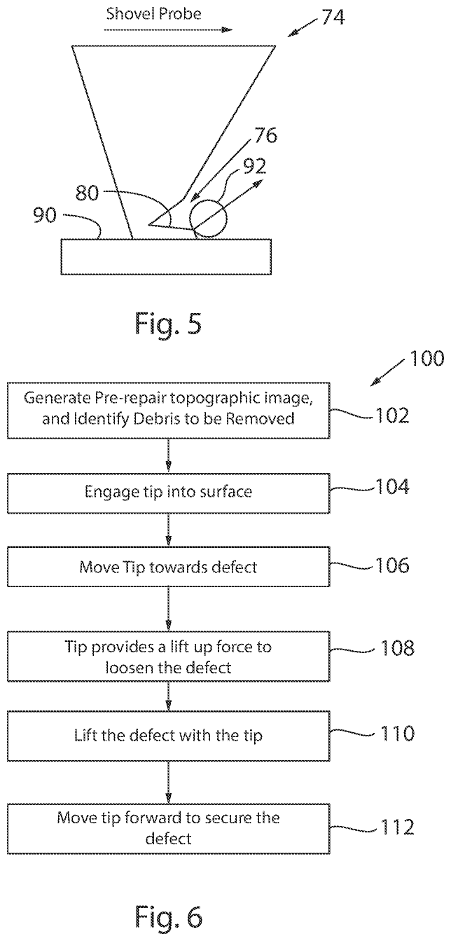

Turning to FIG. 5, tip 74 of the probe of the preferred embodiments is shown as it cleans a surface 90 of debris 92. In comparison to the interaction between probe tip 52 and debris 56 in FIG. 2, in this case, the debris 92 is scooped up as bottom 80 of notch 76 of the tip surface engages the bottom of the debris particle 92. The arrow shown indicates the force on the defect/debris is essentially upward in contrast to a similar operation with a conventional AFM tip in which the force pushes the defect down when the two encounter each other (FIG. 2), possibly smashing the debris to pieces. When the shovel probe 70 of the preferred embodiments exerts lateral forces it engages the defect/debris, and the tip provides a lifting force. The lifting force not only can preserve the defect 92 as a whole piece, but also move the defect into the notch within the tip, improving removal efficiency.

FIG. 6 illustrates a method 100 according to the preferred embodiments. A pre-repair topographic image of the debris and surrounding area is collected using the probe shown in FIG. 4, and location of the debris to be removed is identified in the pre-repair image in Step 102. To clean the sample surface, after AFM start-up, an engage routine is initiated in Step 104. This brings the planar bottom surface of the probe tip into careful contact with the sample surface. Next, the AFM method, in Step 106, provides relative lateral motion to move the tip towards the defect. As the relative motion continues, forces exerted on the debris by the blade of the probe tip exerts a lift up force on the defect, and then loosens the defect and starts to lift it in Step 108. The relative motion is continued (forward along the scan trajectory) so the tip, and more particularly, the notch, lifts the defect in Step 110, and secures the defect in Step 112.

More particularly, the vector direction for debris removal is determined and set in the pre-repair image through a graphical user interface (GUI) linked to the repair control. This vector direction is positioned relative to all other surface features so as to avoid any incidental interaction with surface features other than the debris to be removed. There are usually several parallel vectors in a repair area for any debris removal action.

A location marker is placed in the pre-repair image to define the leading-edge location in the path of the repair vector associated with the debris to be removed using the control GUI. The primary vector direction is typically parallel to the XY plane of the sample surface and provides relative lateral (X-Y) motion until the leading-edge location trigger is reached during the repair vector move.

After reaching the leading-edge trigger location, the repair vector direction changes to orthogonal to the sample XY plane, and provides motion so that the probe moves in Z up away from the XY plane of the sample surface, preferably to a predetermined height. After this upward motion is completed, the repair vector direction returns to parallel with the XY sample plane and continues to complete the requested length of the repair vector if any distance remains after the leading-edge trigger placement.

The AFM then lifts, for example, the probe and returns to the start location for the next repair vector defined is the series of repair vector moves.

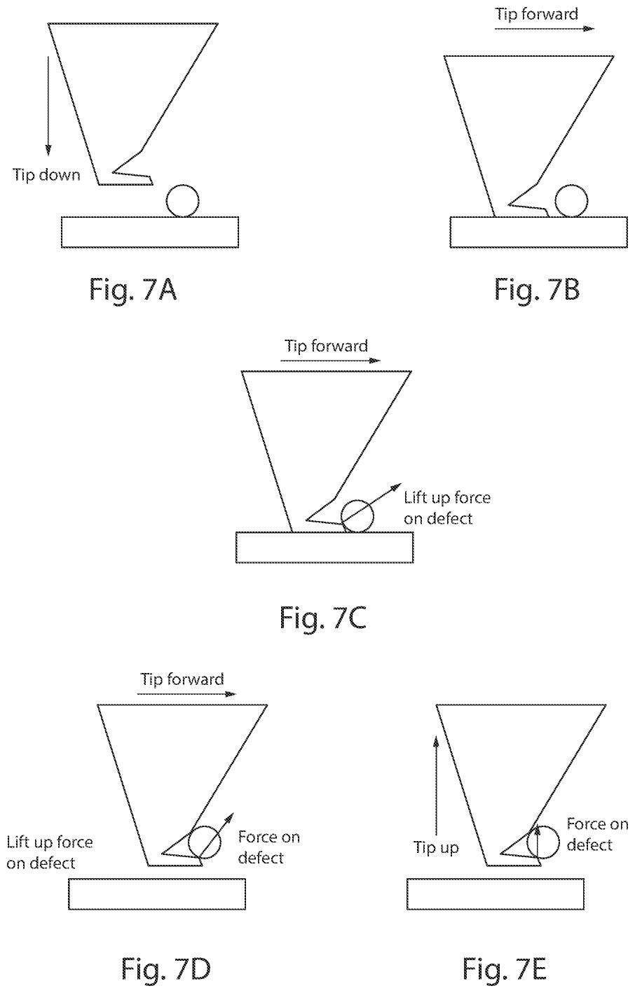

This process is illustrated in more detail in FIGS. 7A-7E. In FIG. 7A, in a system in which the AFM moves the probe laterally and orthogonally to the sample surface, the tip is brought down to the sample surface. The tip is then moved forward towards the debris (FIG. 7B). Then, after engaging the debris, the tip is moved further forward to provide a lift up force to the defect due to engagement of the debris with the wedge shaped blade on the tip, as shown in FIG. 7C). This lifting force loosens the debris. Next, in FIG. 7D, the tip is lifted. This applies an upward force to the debris, lifting the debris up off the sample surface. When the tip is moved forward again, the debris is secured in the notch. As shown in FIG. 7E, the AFM is operated to lift the defect up so the debris can be discarded by tip cleaning, post debris collection.

In summary, the shovel probe is engaged with the surface of the sample at an appropriate height. The probe is then pushed towards the pre-identified defects, with the opening concaved ends moving towards the defect(s). When the shovel tip pushes the defect, the force on the defect is upward. This keeps the defect a whole piece and loosens the defect's attachment with the surface. Due to the forward force, the defect has a larger chance to move towards the concaved portion of the shovel tip.

Then the shovel tip is then lifted upward to hold the defect off the surface. And in the last step, the shovel tip moves forward to secure the defect.

Note that in the focused ion beam (FIB) process, the energy level of the Ga+ beam (ion current) was optimized to mill the notch. In particular, the energy is preferably adjusted to maintain the integrity of the tip material (diamond) while still providing milling efficiency. Well-defined milling masks are used to suppress stray ion beam energy to achieve accurate final diamond tip geometry. The sample (diamond tip) was mounted on a proper sample holder and tilted at certain angles to accommodate the ion milling process. For example, the sample holder may be designed to match the 13° use angle when installed in an AFM, and thereafter adjusted according the milling process employed. Notably, what has been presented here is a preferred geometry, but note that any number of blade shapes could be created using known techniques.

Although the best mode contemplated by the inventors of carrying out the present invention is disclosed above, practice of the present invention is not limited thereto. It will be manifest that various additions, modifications and rearrangements of the features of the present invention may be made without deviating from the spirit and scope of the underlying inventive concept.

What is claimed is:

1. A mechanical device for removing nanoscale debris from a sample surface comprising:
a surface configured to contact a bottom portion of the debris and lift the debris when moved laterally to the sample surface.

2. The device of claim 1, wherein the mechanical device is an AFM probe having a tip, and the surface defines part of the tip.

3. The device of claim 2, wherein the tip is a diamond tip and the surface defines a notch formed between proximal and distal ends of the tip.

4. The device of claim 1, wherein the notch is formed by focus ion beam (FIB) milling.

5. The device of claim 1, wherein the sample surface is a surface of a lithography mask used in semiconductor fabrication.

6. An AFM having a probe according claim 1.

7. A method of cleaning nanoscale debris from a sample surface, the method comprising:
a mechanical device including a surface configured to contact a bottom portion of the debris and lift the debris when moved laterally to the sample surface.

8. The method of claim 7, wherein the mechanical device is an AFM probe having a tip, and the surface defines part of the tip.

9. The method of claim 8, further comprising moving the tip in a vector having both lateral and vertical components resulting in scooping of the debris from the sample surface.

10. The method of claim 8, further comprising:
engaging the tip to the surface; and
providing relative lateral motion between the surface and the tip so that the surface secures the debris against the tip and lifts the debris.

11. The method of claim 10, further comprising AFM imaging the sample surface prior to the engaging step to identify the debris.

12. The method of claim 8, further comprising providing relative orthogonal motion between the probe and the sample so as to lift the debris with the tip to a predetermined height.

13. A method of manufacturing a device to clean nanoscale debris from a sample surface, the method comprising:
providing a probe including a diamond tip; and
modifying the tip such that when the probe is moved laterally to the sample surface and interacts with the nanoscale debris the modified tip contacts a bottom portion of the debris so as to provide an upward force to the debris.

14. The method of claim 13, wherein the tip has a first and second ends, and wherein modifying step comprises cutting a notch in a surface of the tip between the first and second ends.

15. The method of claim 14, wherein, prior to being modified, the tip is generally conical in shape.

16. The method of claim 14, wherein the modifying step includes focused ion beam (FIB) milling the tip.

17. An AFM probe made according to the method of claim 13.
